(19) United States
(12) Patent Application Publication
(10) Pub. No.: US 2011/0271157 A1
(43) Pub. Date: Nov. 3, 2011

(54) TEST CIRCUIT AND SEMICONDUCTOR MEMORY APPARATUS INCLUDING THE SAME

(75) Inventors: Kang Youl LEE, Ichon-shi (KR); Mun Phil Park, Ichon-shi (KR)

(73) Assignee: Hynix Semiconductor Inc., Ichon-shi (KR)

(21) Appl. No.: 12/841,070

(22) Filed: Jul. 21, 2010

(30) Foreign Application Priority Data
Apr. 30, 2010 (KR) 10-2010-0040664

(51) Int. Cl. G11C 29/04; G06F 11/22

(52) U.S. Cl. 714/718; 714/E11.145

(57) ABSTRACT

A test circuit of a semiconductor memory apparatus includes: a first fail detection unit configured to detect a fail of a memory cell group of a first memory block by combining a plurality of first test data signals outputted from the memory cell group of the first memory block; a second fail detection unit configured to detect a fail of a memory cell group of a second memory block by combining a plurality of second test data signals outputted from the memory cell group of the second memory block; a common fail detection unit configured to detect a fail of the memory cell groups of the first and second memory blocks by combining the plurality of first test data signals and the plurality of second test data signals; and a fail determination unit configured to output detection results of the first and second fail detection units or a detection result of the common is fail detection unit according to the detection results of the first and second fail detection units.

### CROSS-REFERENCES TO RELATED APPLICATION

The present application claims priority under 35 U.S.C. §119(a) to Korean Application No. 10-2010-0040664, filed on Apr. 30, 2010, in the Korean Intellectual Property Office, which is incorporated herein by reference in its entirety as if set forth in full.

### BACKGROUND

1. Technical Field

The present invention relates to a semiconductor memory apparatus, and more particularly, to a method for detecting and repairing a fail of semiconductor memory apparatus.

2. Related Art

As the degree of integration of a semiconductor memory apparatus increases, the number of memory cells and signal lines provided in a single semiconductor memory apparatus is rapidly increasing. Since the memory cells are integrated in a limited space, the critical dimension of internal circuits and the size of memory cells are gradually reduced. For these reasons, the possibility of memory cells' failure in a semiconductor memory apparatus increases. In spite of the fail of the memory cells, memories having a desired capacity can be manufactured with high yield because a redundancy circuit and a repair circuit for repairing failed memory cells are provided within a semiconductor memory apparatus.

In general, a variety of tests are performed after a wafer process is completed. When it is determined by the tests that failed memory cells can be repaired, the fail is repaired by replacing the failed memory cells with redundancy memory cells. Accordingly, when addresses corresponding to the failed memory cells are inputted, the redundancy memory cells operate as an alternative to the failed memory cells. Thus, the semiconductor memory apparatus is capable of performing normal operations.

Meanwhile, a compressed test is used to reduce a test time. The compressed test is performed by writing the same data to a plurality of memory cells and compressing and outputting the written data of the plurality of memory cells. Since the semiconductor memory apparatus is divided into a plurality of memory blocks, a rate is of fail detection and an efficiency of repair are determined by arrangement of memory blocks to be tested and the combination of data in the compressed test.

### SUMMARY

In one embodiment of the present invention, a test circuit of a semiconductor memory apparatus includes: a first fail detection unit configured to detect a fail of a memory cell group of a first memory block by combining a plurality of first test data signals outputted from the memory cell group of the first memory block; a second fail detection unit configured to detect a fail of a memory cell group of a second memory block by combining a plurality of second test data signals outputted from the memory cell group of the second memory block; a common fail detection unit configured to detect a fail of the memory cell groups of the first and second memory blocks by combining the plurality of first test data signals and the plurality of second test data signals; and a fail determination unit configured to output detection results of the first and second fail detection units or a detection result of the common fail detection unit according to the detection results of the first and second fail detection units.

In another embodiment of the present invention, a test circuit of a semiconductor memory apparatus includes: a first fail detection unit configured to detect a fail of a memory cell group of a first memory block by combining a plurality of first test data signals outputted from the memory cell group of the first memory block; a is second fail detection unit configured to detect a fail of a memory cell group of a second memory block by combining a plurality of second test data signals outputted from the memory cell group of the second memory block; a common fail detection unit configured to detect the fail of the memory cell groups of the first and second memory blocks by combining the plurality of first test data signals and the plurality of second test data signals; and a selection unit configured to output detection results of the first and second fail detection units or a detection result of the common fail detection unit according to a mode selection signal.

In another embodiment of the present invention, a semiconductor memory apparatus includes: a first fail detection unit configured to detect a fail of a memory cell group of a first memory block by combine a plurality of first test data signals outputted from the memory cell group of the first memory block; a second fail detection unit configured to detect a fail of a memory cell group of a second memory block by combining a plurality of second test data signals outputted from the memory cell group of the second memory block; a common fail detection unit configured to detect a fail of the memory cell groups of the first and second memory blocks by combining the plurality of first test data signals and the plurality of second test data signals; a fail determination unit configured to output detection results of the first and second fail detection units or a detection result of the common fail detection unit; a redundancy memory block including a plurality of redundancy memory cell is groups; and a repair unit configured to replace the memory cell groups of the first and second memory blocks with the redundancy memory cell groups based on the detection result outputted from the fail determination unit.

### BRIEF DESCRIPTION OF THE DRAWINGS

Features, aspects, and embodiments are described in conjunction with the attached drawings, in which:

FIG. 1 is a diagram schematically illustrating a configuration of a semiconductor memory apparatus in accordance with an embodiment of the present invention;

FIG. 2 is a diagram illustrating a configuration of a test unit in FIG. 1 in accordance with a first embodiment of the present invention;

FIG. 3 is a truth table illustrating an operation of the test unit in FIG. 2;

FIG. 4 is a diagram illustrating a configuration of the test unit in FIG. 1 in accordance with a second embodiment of the present invention;

FIG. 5 is a truth table illustrating an operation of the test unit in FIG. 4;

FIG. 6 is a diagram illustrating a configuration of the test unit in FIG. 1 in accordance with a third embodiment of the present invention; and

FIG. 7 is a diagram illustrating a configuration of the test unit in FIG. 1 in accordance with a fourth embodiment of the present invention.

### DETAILED DESCRIPTION

Reference will now be made in detail to the exemplary embodiments consistent with the present disclosure, examples of which are illustrated in the accompanying drawings. Whenever possible, the same reference numerals will be used throughout the drawings to refer to the same or like parts.

For reference, since terms, symbols and signs in drawings and in this detailed description to designate devices, blocks, and so on may be used for detailed units as the occasion demands, it is to be noted that the same terms, symbols and signs may not designate the same devices, blocks, and so on in an entire circuitry. Also, the logic signals of a circuit and binary data values are divided into a high level (H) or a low level (L) in correspondence to voltage levels, and may be represented as ‘1’ and ‘0’. Furthermore, as the occasion demands, a high impedance state (a high-Z state) may be defined and described.

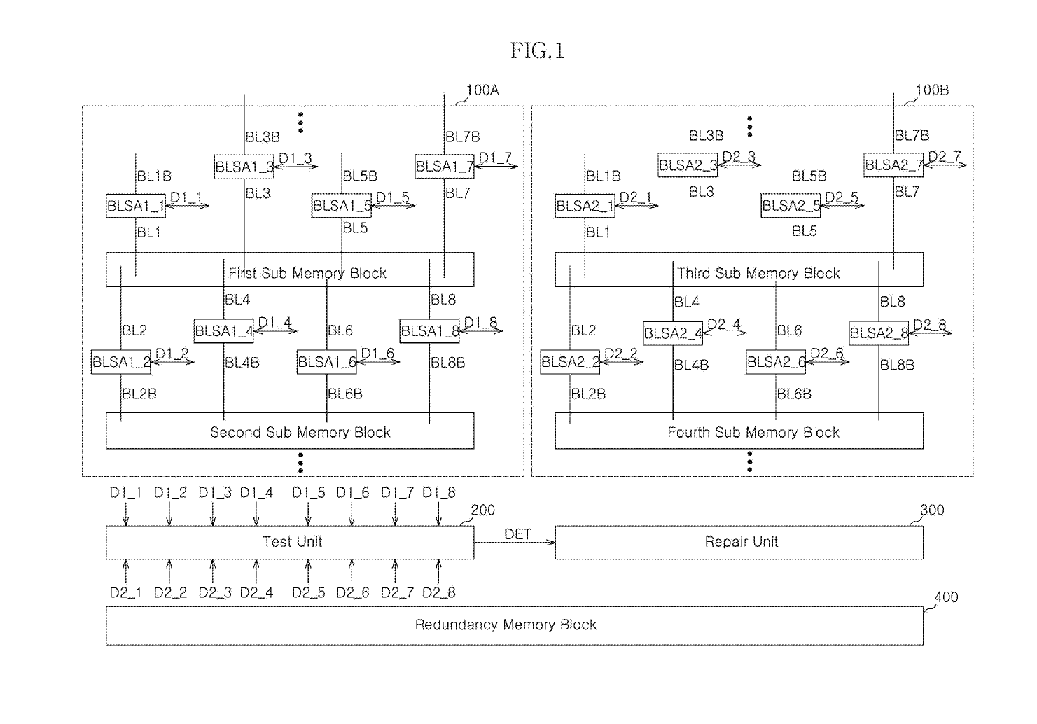

FIG. 1 is a diagram schematically illustrating a configuration of a semiconductor memory apparatus in accordance with an embodiment of the present invention.

The semiconductor memory apparatus in accordance with an embodiment of the present invention may include a simple configuration for clear explanation of the technical principles of the present invention.

Referring to FIG. 1, the semiconductor memory apparatus may include a plurality of memory blocks 100A and 100B, a test unit 200, a repair unit 300, and a redundancy memory block 400.

The detailed configuration and principal operation of the semiconductor memory apparatus configured as described above will be described below.

The plurality of memory blocks 100A and 100B include a first memory block 100A and a second memory block 100B. The first memory block 100A is divided into a first sub memory block and a second sub memory block, and each of the sub memory blocks includes a plurality of memory cells. Also, the second memory block 100B is divided into a third sub memory block and a fourth sub memory block, and each of the sub memory blocks includes a plurality of memory cells. In general, the plurality of memory cells are configured to input/output data in units of groups.

A plurality of bit line sense amplification units BLSA1_1-BLSA1_8 allocated to the first memory block 100A exchange data with the memory cells of the first and second sub memory blocks through bit lines BL. The plurality of bit line sense amplification units BLSA1_1-BLSA1_8 sense and amplify data of the memory cells transferred through the bit lines in a data read operation mode, and output the amplified data to the outside. Also, the plurality of bit line sense amplification units BLSA1_1-BLSA1_8 transfer external data through the bit lines to the memory cells in a data write operation mode. The semiconductor memory apparatus according to the embodiment may be designed in an open bit line architecture. For example, in the second bit line sense amplification unit BLSA1_2 of the first memory block 100A, a bit line BL2 of the second bit line sense amplification unit BLSA1_2 is allocated to the first sub memory block, and a bit line bar BL2B of the second bit line sense amplification unit BLSA1_2 is allocated to the second sub memory block.

Since the second memory block 100B has the same configuration as the first memory block 100A, detailed description thereof will be omitted.

In a compressed test, the same test data is stored in a selected memory cell group, and a plurality of test data signals outputted from the memory cell group are compressed and outputted. A repair circuit replaces the corresponding memory cell group with a redundancy memory cell group according to a compressed fail detection result.

The test unit 200 detects the fail of the corresponding memory cell group based on a plurality of first test data signals D1_1-D1_8 outputted from the memory cell group of the first memory block 100A and a plurality of second test data signals D2_1-D2_8 outputted from the memory cell group of the second memory block 100B.

Furthermore, the repair unit 300 replaces the memory cell group, which is determined to be a failed memory cell group based on the detection result of the test unit 200, with the redundancy is memory cell group of the redundancy memory block 400. The redundancy memory block 400 includes a plurality of redundancy memory cell groups. Although the redundancy memory block 400 and the memory blocks 100A and 100B are separately provided in FIG. 1, a plurality of redundancy memory cell groups may be disposed within the memory blocks 100A and 100B.

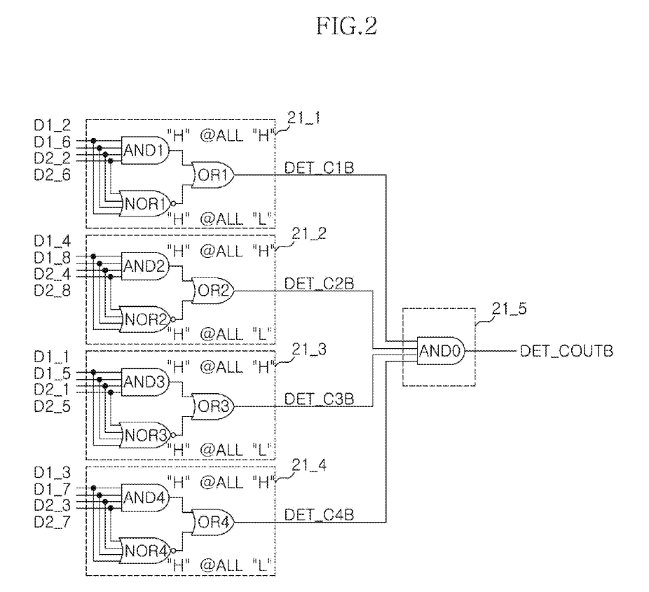

FIG. 2 is a diagram illustrating a configuration of a test unit in FIG. 1 in accordance with a first embodiment of the present invention.

Referring to FIG. 2, the test unit simultaneously detects the fail of the corresponding memory cell groups of the first and second memory blocks 100A and 100B by combining the plurality of first test data signals D1_1-D1_8 outputted from the memory cell group of the first memory block 100A and the plurality of second test data signals D2_1-D2_8 outputted from the memory cell group of the second memory block 100B.

When any one memory cell among the memory cell groups of the first memory block 100A and the memory cell groups of the second memory block 100B is failed, the test unit outputs a detection result that all memory cell groups of the first and second memory blocks 100A and 100B have failed.

The test unit may include a plurality of sub common fail detection sections 21_1-21_4 and a signal combination section 21_5. The plurality of common fail detection sections 21_1-21_4 combine the plurality of first test data signals D1_1-D1_8 and the plurality of is second test data signals D2_1-D2_8 as many as the allocated number, and output a plurality of sub common fail detection signals DET_C1B-DET_C4B. Since the plurality of sub common fail detection sections 21_1-21_4 have the same configuration and perform the same operation, the first sub common fail detection section 21_1 will be representatively described.

The first sub common fail detection section 21_1 may include an exclusive NOR (XNOR) logic. The XNOR logic may consist of an ANDing element AND1, a NORing element NOR1, and an ORing element OR1.

The first sub common fail detection section 21_1 outputs the first sub common fail detection signal DET_C1B by performing an XNOR operation on the two test data signals D1_2 and D1_6, which are allocated thereto among the plurality of first test data signals D1_1-D1_8 outputted from the first memory block 100A, and the two test data signals D2_2 and D2_6, which are allocated thereto among the plurality of second test data signals D2_1-D2_8 outputted from the second memory block 100B. Therefore, when the four test data signals D1_2, D1_6, D2_2 and D2_6 have the same data value, the first sub common fail detection signal DET_C1B is deactivated to a high level. This means that no fail is detected. When any one of the four test data signals D1_2, D1_6, D2_2 and D2_6 has a different data value, the first sub common fail detection signal DET_C1B is activated to a low level. This means that the fail is detected. Since the fail is detected by combining the four test data is signals D1_2, D1_6, D2_2 and D2_6, such a test is also called a 4-bit compressed test.

The signal combination section 21_5 outputs a common fail detection signal DET_COUTB by combining the plurality of sub common fail detection signals DET_C1B-DET_C4B. The signal combination section 21_5 outputs the common fail detection signal DET_COUTB by ANDing the plurality of sub common fail detection signals DET_C1B-DET_C4B. In this embodiment, the signal combination section 21_5 may include an ANDing element AND0. If the second to fourth sub common fail detection signals DET_C2B-DET_C4B are deactivated to a high level and only the first sub command fail detection signal DET_C1B is activated to a low level, the common fail detection signal DET_COUTB is activated to a low level and the test unit outputs a detection result that the corresponding memory cell groups of the first and second memory blocks 100A and 100B have failed.

Therefore, since the repair operation is performed based on the common fail detection signal DET_COUTB, the corresponding memory cell groups of the first and second memory blocks 100A and 100B are simultaneously replaced with the redundancy memory cell groups. In such a repair operation, corresponding two memory cell groups of the first and second memory blocks 100A and 100B are simultaneously replaced with the redundancy memory cell groups when any one of the memory cell groups of the first and second memory blocks 100A and 100B is detected as failed.

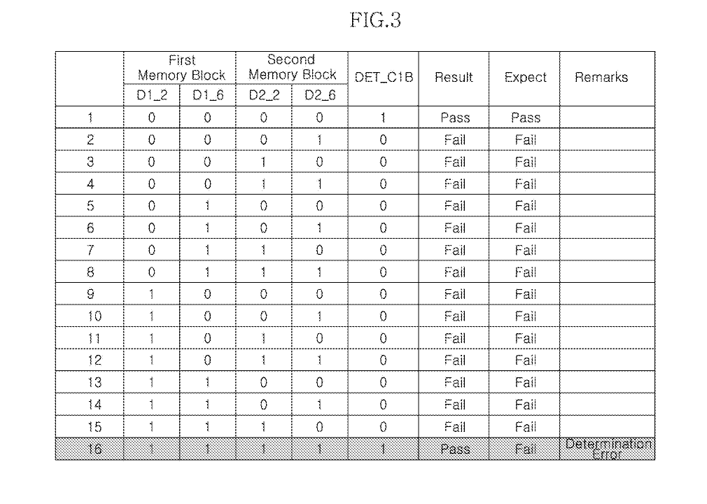

FIG. 3 is a truth table illustrating an operation of the test unit in FIG. 2.

FIG. 3 shows the result from the internal operation of the first sub common fail detection section 21_1. The internal operation of the first sub common fail detection section 21_1 will be described with reference to the truth table in FIG. 3 and FIG. 2. It is assumed that the memory cells are normal when the four test data signals D1_2, D1_6, D2_2 and D2_6 are outputted as ‘0’.

First, when the four test data signals D1_2, D1_6, D2_2 and D2_6 are ‘0’, the first sub common fail detection signal DET_C1B is deactivated to a high level and thus a detection result that no fail is detected is outputted.

Next, when any one of the four test data signals D1_2, D1_6, D2_2 and D2_6 is ‘1’, the first sub common fail detection signal DET_C1B is activated to a low level and thus a detection result that the fail is detected is outputted.

Next, when the four test data signals D1_2, D1_6, D2_2 and D2_6 are ‘1’, the fail must be detected. However, the first sub common fail detection signal DET_C1B is deactivated to a high level and thus a detection result that it is normal is outputted. The probability that the 4-bit compressed test performs such incorrect determination is arithmetically 6.25%, but the probability that all memory cells have failed simultaneously is very low because the four test data signals D1_2, D1_6, D2_2 and D2_6 are outputted from memory cells which are not adjacent to one another.

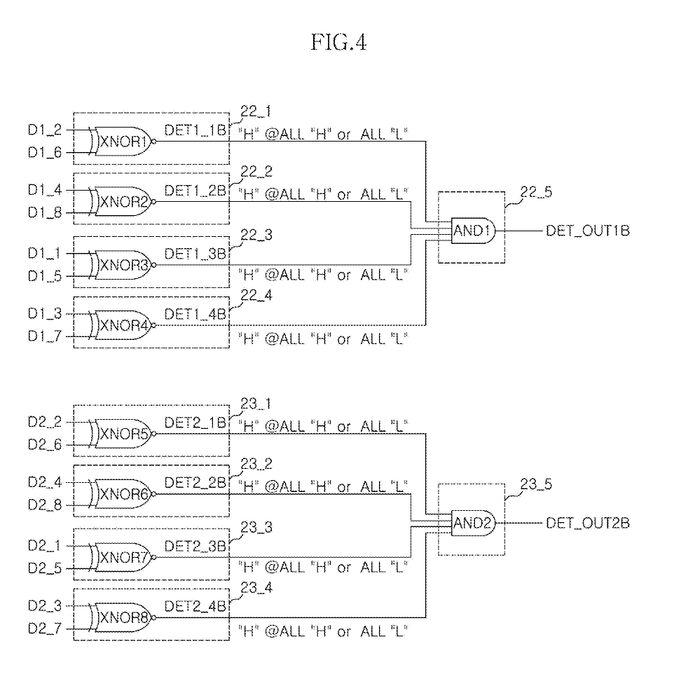

FIG. 4 is a diagram illustrating a configuration of the test unit in FIG. 1 in accordance with a second embodiment of the present invention.

Referring to FIG. 4, the test unit may include a first fail detection section 22_1-22_5 and a second fail detection section 23_1-23_5.

The first fail detection section 22_1-22_5 detects the fail of memory cell groups of the first memory block 100A by combining the plurality of first test data signals D1_1-D1_8 outputted from the memory cell groups of the first memory block 100A. The first fail detection section 22_1-22_5 may include a plurality of first sub fail detection sections 22_1-22_4 and a first signal combination section 22_5. The plurality of first sub fail detection sections 22_1-22_4 combine the plurality of first test data signals D1_1-D1_8 as many as the allocated number, and output a plurality of first sub fail detection signals DET1_1B-DET1_4B.

Since the plurality of first sub fail detection sections 21_1-21_4 have the same configuration and perform the same operation, the first sub fail detection section 21_1 will be representatively described.

The first sub fail detection section 21_1 includes an XNOR logic. The first sub fail detection section 21_1 outputs the first sub fail detection signal DET1_1B by XNORing the two test data signals D1_2 and D1_6, which are allocated thereto among the plurality of first test data signals D1_1-D1_8. Therefore, when the two test data signals D1_2 and D1_6 have the same data value, the first sub fail detection signal DET1_1B is deactivated to a high level. This means that no fail is detected. When the two test data signals D1_2 and D1_6 have a different data value, the first sub fail detection signal DET1_1B is activated to a low level. This means that the fail is detected. Since the fail is detected by combining the two test data signals D1_2 and D1_6, such a test is also called a 2-bit compressed test.

The first signal combination section 22_5 outputs a first fail detection signal DET_OUT1B by combining the plurality of first sub fail detection signals DET1_1B-DET1_4B. The first signal combination section 22_5 outputs the first fail detection signal DET_OUT1B by ANDing the plurality of first sub fail detection signals DET1_1B-DET1_4B. In this embodiment, the first signal combination section 22_5 may include an ANDing element AND1. If three of the first sub fail detection signals DET1_2B-DET1_4B are deactivated to a high level and only one of the first sub fail detection signal DET1_1B is activated to a low level, the first fail detection signal DET_OUT1B is activated to a low level and the test unit outputs a detection result that the corresponding memory cell groups of the first memory block 100A have failed. That is, when any one of the plurality of first sub fail detection signals DET1_1B-DET1_4B is activated to a low level, the first fail detection signal DET_OUT1B is activated to a low level and thus the test unit outputs a detection result that the corresponding memory cell groups of the first memory is block 100A have failed.

The second fail detection section 23_1-23_5 detects the fail of memory cell groups of the second memory block 100B by combining the plurality of second test data signals D2_1-D2_8 outputted from the memory cell groups of the second memory block 100B. The second fail detection section 23_1-23_5 may include a plurality of second sub fail detection sections 23_1-23_4 and a second signal combination section 23_5. The plurality of second sub fail detection sections 23_1-23_4 combine the plurality of second test data signals D2_1-D2_8 as many as the allocated number, and output a plurality of second sub fail detection signals DET2_1B-DET2_{—}4B.

Since the plurality of second sub fail detection sections 23_1-23_4 have the same configuration and perform the same operation, the second sub fail detection section 23_1 will be representatively described.

The second sub fail detection section 23_1 includes an XNOR logic. The second sub fail detection section 23_1 outputs the second sub fail detection signal DET2_1B by performing an XNOR operation on the two test data signals D2_2 and D2_6, which are allocated thereto among the plurality of second test data signals D2_1-D2_8. Therefore, when the two test data signals D2_2 and D2_6 have the same data value, the second sub fail detection signal DET2_1B is deactivated to a high level. This means that no fail is detected. When the two test data signals D2_2 and D2_6 have a different data value, the second sub fail detection signal DET2_1B is activated to a low level. This means that the fail is detected.

The second signal combination section 23_5 outputs a second fail detection signal DET_OUT2B by combining the plurality of second sub fail detection signals DET2_1B-DET2_4B. The second signal combination section 23_5 outputs the second fail detection signal DET_OUT2B by ANDing the plurality of second sub fail detection signals DET2_1B-DET2_4B. In this embodiment, the second signal combination section 23_5 may include an ANDing element AND2. If three of the second sub fail detection signals DET2_2B-DET2_4B are deactivated to a high level and only one of the second sub fail detection signal DET2_1B is activated to a low level, the second fail detection signal DET_OUT2B is activated to a low level and the test unit outputs a detection result that the corresponding memory cell groups of the second memory block 100B have failed. That is, when any one of the plurality of second sub fail detection signals DET2_1B-DET2_4B is activated to a low level, the second fail detection signal DET_OUT2B is activated to a low level and thus the test unit outputs a detection result that the corresponding memory cell groups of the second memory block 100B have failed.

Therefore, since the repair operation is performed based on the first fail detection signal DET_OUT1B and the second fail detection signal DET_OUT2B, the corresponding memory cell groups of the first memory block 100A and the corresponding memory cell groups of the second memory block 100B are respectively replaced with the is redundancy memory cell groups. In such a repair operation, when any one of the memory cell groups of the first and second memory blocks 100A and 100B is detected as a failed memory cell group, only the failed memory cell group of the memory blocks is replaced with the redundancy memory cell groups.

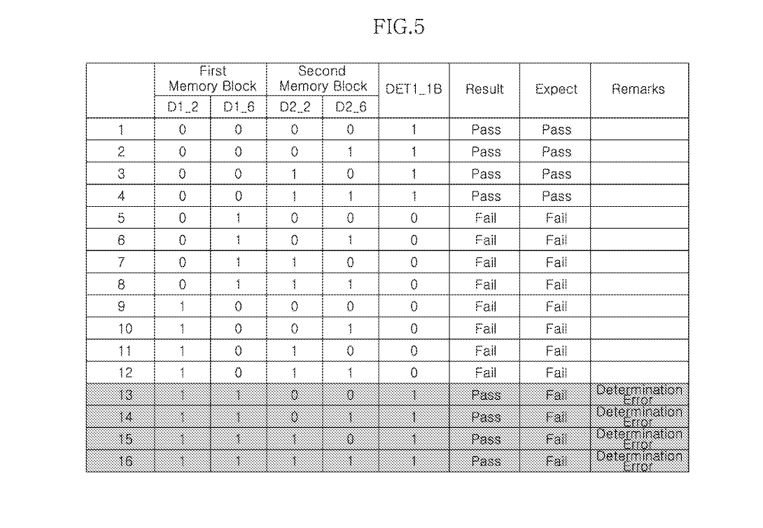

FIG. 5 is a truth table illustrating an operation of the test unit in FIG. 4.

FIG. 5 shows the result from the internal operation of the first sub fail detection section 22_1 and the second sub fail detection section 23_1. The internal operation of the first sub fail detection section 21_1 and the second sub fail detection section 23_1 will be described with reference to the truth table in FIG. 5 and FIG. 4. It is assumed that the memory cells are normal when the two first test data signals D1_2 and D1_6 are outputted as ‘0.’ The two second test data signals D2_2 and D2_6 inputted to the second sub fail detection section 23_1 are shown for reference. Also, it is assumed that the first sub fail detection section 22_1 and the second sub fail detection section 23_1 are operated as a set.

First, when the two first test data signals D1_2 and D1_6 are ‘0’, the first sub fail detection signal DET1_1B is deactivated to a high level and thus a detection result that no fail is detected is outputted.

Next, when any one of the two first test data signals D1_2 and D1_6 is ‘1’, the first sub fail detection signal DET1_1B is activated to a low level and thus a detection result that the fail is detected is outputted.

Next, when the two first test data signals D1_2 and D1_6 are ‘1’, the fail must be detected. However, the first sub fail detection signal DET1_1B is deactivated to a high level and thus a detection result that it is normal is outputted. The probability that the 2-bit compressed test performs an incorrect determination is arithmetically 25%.

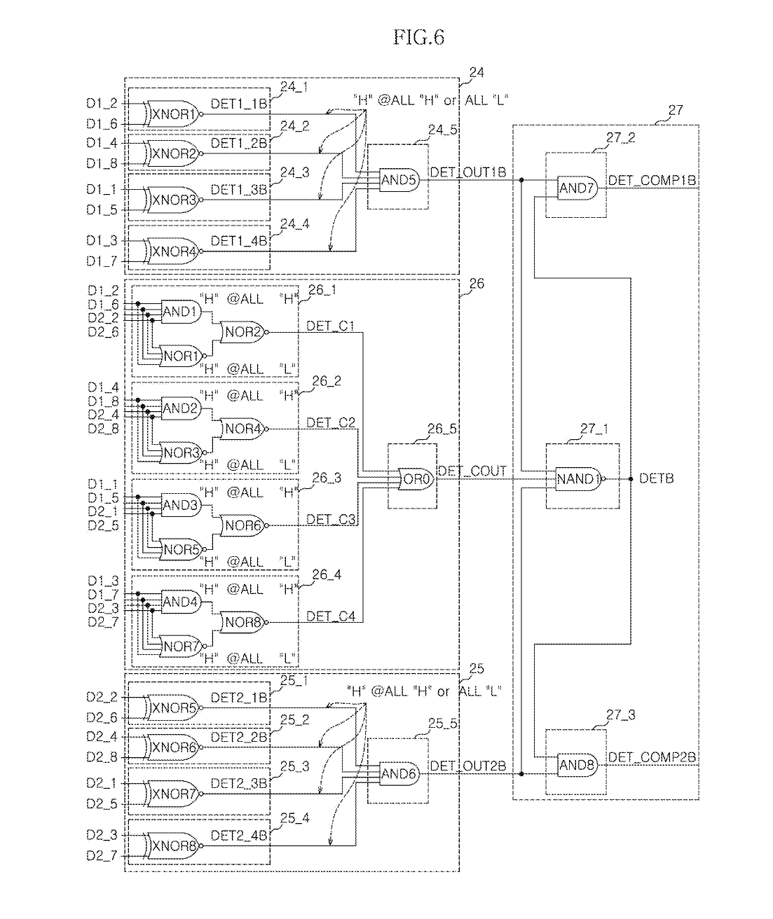

FIG. 6 is a diagram illustrating a configuration of the test unit in FIG. 1 in accordance with a third embodiment of the present invention.

Referring to FIG. 6, the test unit may include a first fail detection section 24, a second fail detection section 25, a common fail detection section 26, and a fail determination section 27.

The detailed configuration and principal operation of the test unit configured as above will be described below.

The first fail detection section 24 detects the fail of memory cell groups of the first memory block 100A by combining a plurality of first test data signals D1_1-D1_8 outputted from the memory cell groups of the first memory block 100A. That is, the first fail detection section 24 detects the fail based on the plurality of first test data signals D1_1-D1_8 and activates a first fail detection signal DET_OUT1B to a low level when the fail is detected. Since the first fail detection section 24 may have substantially identical configuration with the first fail detection section 22_1-22_5 of the test unit in FIG. 4, duplicate description thereof will be omitted.

The second fail detection section 25 detects the fail of memory cell groups of the second memory block 100B by combining a plurality of second test data signals D2_1-D2_8 outputted from the memory cell groups of the second memory block 100B. That is, the second fail detection section 25 detects the fail based on the plurality of second test data signals D2_1-D2_8 and activates a second fail detection signal DET_OUT2B to a low level when the fail is detected. Since the second fail detection section 25 may have substantially identical configuration with the second fail detection section 23_1-23_5 of the test unit in FIG. 4, duplicate description thereof will be omitted.

The common fail detection section 26 detects the fail of the memory cell groups of the first and second memory blocks 100A and 1006 simultaneously by combining the plurality of first test data signals D1_1-D1_8, which are outputted from the memory cell groups of the first memory block 100A, and the plurality of second test data signals D2_1-D2_8, which are outputted from the memory cell groups of the second memory block 1006.

When any one memory cell among the memory cell groups of the first memory block 100A and the memory cell groups of the second memory block 1006 is failed, the common fail detection section 26 outputs a detection result that all memory cell groups of the first and second memory blocks 100A and 1006 have failed.

The common fail detection section 26 may include a plurality of sub common fail detection sections 26_1-26_4 and a signal combination section 26_5. The plurality of sub common fail detection sections 26_1-26_4 combine the plurality of first test data signals D1_1-D1_8 and the plurality of second test data signals D2_1-D2_8 as many as the allocated number, and output a plurality of sub common fail detection signals DET_C1-DET_C4. Since the plurality of sub common fail detection sections 26_1-26_4 have the same configuration and perform the same operation, the first sub common fail detection section 26_1 will be representatively described.

The first sub common fail detection section 26_1 may include an XNOR logic. The XNOR logic includes an ANDing element AND1, a first NORing element NOR1, and a second NORing element NOR2.

The first sub common fail detection section 26_1 outputs the first sub common fail detection signal DET_C1 by performing an XNOR operation on the two test data signals D1_2 and D1_6, which are allocated thereto among the plurality of first test data signals D1_1-D1_8 outputted from the first memory block 100A, and the two test data signals D2_2 and D2_6 which are allocated thereto among the plurality of second test data signals D2_1-D2_8 outputted from the second memory block 100B. Therefore, when the four test data signals D1_2, D1_6, D2_2 and D2_6 have the same data value, the first sub common fail detection signal DET_C1 is deactivated to a low level. This means that no fail is detected. When any one of the four test data signals D1_2, D1_6, D2_2 and D2_6 has a different data value, the first sub common fail detection signal DET_C1 is activated to a high level. This means that the fail is detected. Since the fail is detected by combining the four test data signals D1_2, D1_6, D2_2 and D2_6, such a test is also called a 4-bit compressed test.

The signal combination section 26_5 outputs a common fail detection signal DET_COUT by combining the plurality of sub common fail detection signals DET_C1-DET_C4. The signal combination section 26_5 outputs the common fail detection signal DET_COUT by ANDing the plurality of sub common fail detection signals DET_C1-DET_C4. In this embodiment, the signal combination section 26_5 may include an ORing element OR0. If the second to fourth sub common fail detection signals DET_C2-DET_C4 are deactivated to a low level and only the first sub common fail detection signal DET_C1 is activated to a high level, the common fail detection signal DET_COUT is activated to a high level and the test unit outputs a detection result that the corresponding memory cell groups of the first and second memory blocks 100A and 100B have failed.

The fail determination section 27 outputs the fail detection results of the first and second fail detection sections 24 and 25 or the fail detection result of the common fail detection section 26 as a final fail detection result according to the fail detection results of the first and second fail detection sections 24 and 25. When one of the first fail detection section 24 and the second fail detection section 25 detects the fail of the memory cell group of the corresponding memory block, the fail determination section 27 outputs the detection result of the fail detection section, which detects the fail, as the final fail detection result. When the first fail detection section 24 and the second fail detection section 25 detect no fail in the memory cell groups of the corresponding memory blocks, the fail determination section 27 outputs the detection result of the common fail detection section 26 as the final fail detection result.

In this embodiment, the fail determination section 27 may include a fail detection combination section 27_1, a first signal output section 27_2, and a second signal output section 27_3.

The fail detection combination section 27_1 outputs a fail combination signal DETB by combining the first fail detection signal DET_OUT1B outputted from the first fail detection section 24, the second fail detection signal DET_OUT2B outputted from the second fail detection section 25, and the common fail detection signal DET_COUT outputted from the common fail detection section 26. The fail detection combination section 27_1 may include a NANDing element NAND1 configured to output the fail combination signal DETB by NANDing the first fail detection signal DET_OUT1B, the second fail detection signal DET_OUT2B, and the common fail detection signal DET_COUT.

The first signal output section 27_2 outputs a first final fail detection signal DET_COMP1B by combining the fail combination signal DETB and the first fail detection signal DET_OUT1B. The first signal output section 27_2 may include an ANDing element AND7 configured to output the first final fail detection signal DET_COMP1B by ANDing the fail combination signal DETB and the first fail detection signal DET_OUT1B.

The second signal output section 27_3 outputs a second final fail detection signal DET_COMP2B by combining the fail combination signal DETB and the second fail detection signal DET_OUT2B. The second signal output section 27_3 may include an ANDing element AND8 configured to output the second final fail detection signal DET_COMP2B by ANDing the fail combination signal DETB and the second fail detection signal DET_OUT2B.

The detailed internal operation of the fail determination section 27 will be described below.

First, it is assumed that one of the first fail detection signal DET_OUT1B and the second fail detection signal DET_OUT2B is activated to a low level. Thus the signal indicates that the fail occurs in the memory cell group of the first memory block 100A or the memory cell group of the second memory block 100B. Further, it is assumed that the first fail detection signal DET_OUT1B is activated to a low level and thus the fail occurs in the memory cell group of the first memory block 100A.

Since the first fail detection signal DET_OUT1B is activated to a low level, the fail detection combination section 27_1 outputs the fail combination signal DETB having a high level. Therefore, the first signal output section 27_2 activates the first final fail detection signal DET_COMP1B to a low level. The fail determination section 27 indicates through the first final fail detection signal DET_COMP1B that the fail occurs in the memory cell group of the first memory block 100A. That is, when one of the first fail detection section 24 and the second fail detection section 25 detects the fail of the memory cell group of the corresponding memory block, the fail determination section 27 outputs the detection result of the fail detection section detecting the fail as the final fail detection result.

Next, it is assumed that the first fail detection signal DET_OUT1B and the second fail detection signal DET_OUT2B are deactivated to a high level. Thus the signals indicate that the memory cell group of the first memory block 100A or the memory cell group of the second memory block 100B is normal. Further it is assumed that, in spite of the signals' indication, a fail occurs in any one memory block, which means that a determination error occurs in the 2-bit compressed test.

Since the first fail detection signal DET_OUT1B and the second fail detection signal DET_OUT2B are deactivated to a high level, the fail combination signal DETB outputted from the fail detection combination section 27_1 is determined by the level of the common fail detection signal DET_COUT. When the common fail detection signal DET_COUT is activated to a high level since the fail is detected, the fail detection combination section 27_1 outputs the fail combination signal DETB having a low level. Accordingly, the first signal output section 27_2 activates the first final fail detection signal DET_COMP1B to a low level, and the second signal output section 27_3 activates the second final fail detection signal DET_COMP2B to a low level. The fail determination section 27 indicates through the first and second final fail detection signals DET_COMP1B and DET_COMP2B that the fail occurs in the memory cell groups of the first and second memory blocks 100A and 100B. In other words, when the first fail detection section 24 and the second fail detection section 25 detect no fail of the memory cell groups of the corresponding memory blocks, the fail determination section 27 outputs the detection result of the common fail detection section 26 as the final fail detection result. Therefore, the fail determination section 27 reduces the determination error by outputting the detection result of the common fail detection section 26 even though the fail detection section 24 and the second fail detection section 25 make an incorrect determination.

When the repair operation of the semiconductor memory apparatus is performed based on the first final fail detection signal DET_COMP1B and the second final fail detection signal DET_COMP2B, each memory block including the failed memory cell groups may be replaced with the redundancy memory cell groups. Alternatively, memory blocks including the failed memory cell groups and the memory blocks tested together with such memory blocks may be replaced with the redundancy memory cell groups simultaneously.

That is, upon the operation of repairing the first and second memory blocks 100A and 100B based on the final fail detection result outputted from the fail determination section 27, when the fail determination section 27 outputs the fail detection result of the first fail detection section 24 or the second fail detection section 25 as the final fail detection result, the repair circuit of the semiconductor memory apparatus performs an operation of replacing only the failed memory cell group of the memory block with the redundancy memory cell group. When the fail determination section 27 outputs the fail detection result of the common fail detection section 26 as the final fail detection result, the repair circuit of the semiconductor memory apparatus performs an operation of simultaneously replacing the corresponding memory cell groups of the first and second memory blocks 100A and 100B with the redundancy memory cell groups. Therefore, the semiconductor memory apparatus including the test unit in FIG. 6 may reduce the fail determination error, and replace only the failed memory cells with the redundancy memory cells, thereby improving the repair efficiency.

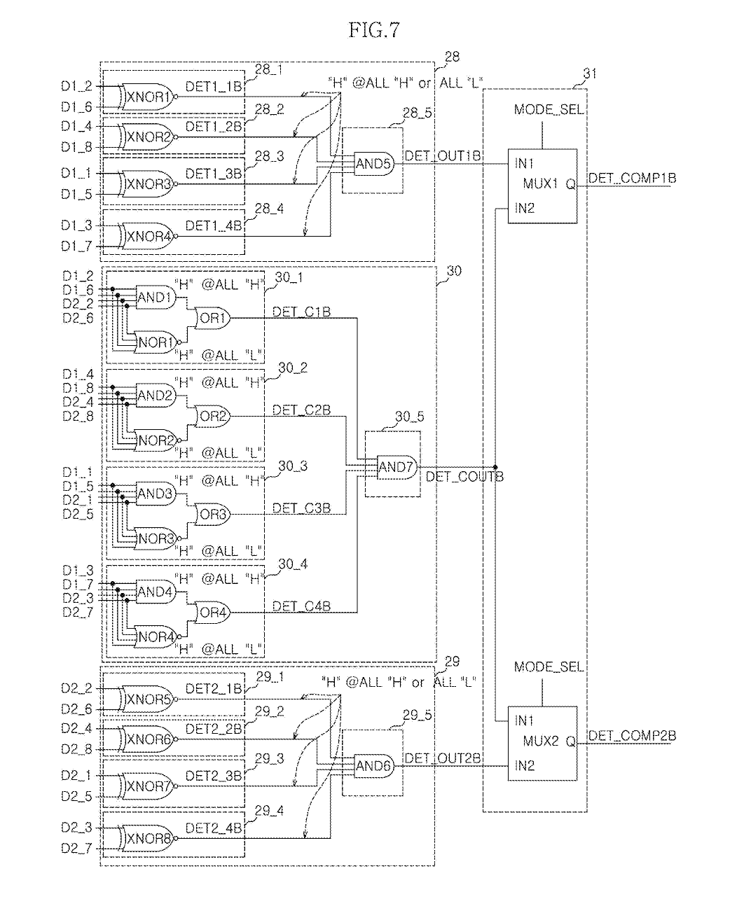

FIG. 7 is a diagram illustrating a configuration of the test unit in FIG. 1 in accordance with a fourth embodiment of the present invention.

Referring to FIG. 7, the test unit may include a first fail detection section 28, a second fail detection section 29, a common fail detection section 30, and a selection section 31. Since the first fail detection section 28, the second fail detection section 29, and the command fail detection section 30 have been described in detail through the operations of the test units according to the first to third embodiments, duplicate description thereof will be omitted and only their principal operations will be described below.

The first fail detection section 28 detects the fail of memory cell groups of the first memory block 100A by combining a plurality of first test data signals D1_1-D1_8 outputted from the memory cell groups of the first memory block 100A. That is, the first fail detection section 28 detects the fail based on the plurality of first test data signals D1_1-D1_8 and activates a first fail detection signal DET_OUT1B to a low level when the fail is detected.

The second fail detection section 29 detects the fail of memory cell groups of the second memory block 100B by combining a plurality of second test data signals D2_1-D2_8 outputted from the memory cell groups of the second memory block 100B. That is, the second fail detection section 29 detects the fail based on the plurality of second test data signals D2_1-D2_8 and activates a second fail detection signal DET_OUT2B to a low level when the fail is detected.

The common fail detection section 30 simultaneously detects the fail of the memory cell groups of the first and second memory blocks 100A and 100B by combining the plurality of first test data signals D1_1-D1_8, which are outputted from the memory cell groups of the first memory block 100A, and the plurality of second test data signals D2_1-D2_8, which are outputted from the memory cell groups of the second memory block 100B. When the fail is detected, the common fail detection section 30 activates the common fail detection signal DET_COUTB to a low level.

The selection section 31 outputs the detection results of the first and second fail detection sections 28 and 29 or the detection result of the common fail detection section 30 as a final fail detection result according to a mode selection signal MODE_SEL. The mode selection signal MODE_SEL is a selection signal for determining the fail detection section whose fail detection result is to be outputted. The mode selection signal MODE_SEL may be defined as a signal directly inputted from a mode register set (MRS), a repair related control circuit or the outside. Also, the mode selection signal MODE_SEL may be defined as a signal representing a wafer test or a package test.

The selection section 31 may include a plurality of switches MUX1 and MUX2. When the mode selection signal MODE_SEL is activated, the plurality of switches MUX1 and MUX2 output the common fail detection signal DET_COUTB outputted from the common fail detection section 30 as the final fail detection signals DET_COMP1B and DET_COMP2B. When the mode selection signal MODE_SEL is deactivated, the plurality of switches MUX1 and MUX2 output the first fail detection signal DET_OUT1B outputted from the first fail detection section 28 and the second fail detection signal DET_OUT2B outputted from the second fail detection section 29 as the final fail detection signals DET_COMP1B and DET_COMP2B.

As described above, the test circuit of the semiconductor memory apparatus can improve the fail detection rate and the repair efficiency.

For reference, embodiments including additional component elements may be exemplified in order to describe the present invention in further detail. Moreover, an active high configuration or an active low configuration for indicating the activated states of signals and circuits may vary depending upon an embodiment. It is to be understood that the configurations of transistors and logic gates may be changed in order to realize the same function as the occasion demands. That is to say, NANDing elements, NORing elements, etc. can be configured by various combinations of NAND gates, NOR gates, inverters, and so forth. Since these circuit changes have a large number of cases and can be easily inferred by those skilled in the art, the enumeration thereof will be omitted herein.

While certain embodiments have been described above with reference to illustrative examples for particular applications, it will be understood to those skilled in the art that the embodiments described are by way of example only. Those skilled in the art with access to the teachings provided in this disclosure will recognize additional modifications, applications, and/or embodiments and additional fields in which the present disclosure would be of significant utility. Accordingly, the test circuit and the semiconductor memory apparatus described herein should not be limited based on the described embodiments. Rather, the test circuit and the semiconductor memory apparatus described herein should only be limited in light of the claims that follow when taken in conjunction with the above description and accompanying drawings.

What is claimed is:

1. A test circuit of a semiconductor memory apparatus, comprising:
a first fail detection unit configured to detect a fail of a memory cell group of a first memory block by combining a plurality of first test data signals outputted from the memory cell group of the first memory block;
a second fail detection unit configured to detect a fail of a memory cell group of a second memory block by combining a plurality of second test data signals outputted from the memory cell group of the second memory block;
a common fail detection unit configured to detect a fail of the memory cell groups of the first and second memory blocks by combining the plurality of first test data signals and the plurality of second test data signals; and
a fail determination unit configured to output detection results of the first and second fail detection units or a detection result of the common fail detection unit according to the detection results of the first and second fail detection units.

2. The test circuit according to claim 1, wherein the common fail detection unit outputs the detection result that the memory cell groups of the first and second memory blocks are failed when any one of the memory cell groups of the first memory block and the second memory block is failed.

3. The test circuit according to claim 1,
wherein, when one of the first fail detection unit and the second fail detection unit detects the fail of the memory cell group of the corresponding memory block, the fail determination unit outputs the detection result of the fail detection unit that detects the fail, and
wherein, when the first fail detection unit and the second fail detection unit detect no fail in the memory cell groups of the corresponding memory blocks, the fail determination unit outputs the detection result of the common fail detection unit.

4. The test circuit according to claim 1, wherein the first fail detection unit comprises:
a plurality of first sub fail detection sections configured to output a plurality of first sub fail detection signals by combining the plurality of first test data signals; and
a signal combination section configured to output a first fail detection signal by combining the plurality of first sub fail detection signals.

5. The test circuit according to claim 1, wherein the second fail detection unit comprises:
a plurality of second sub fail detection sections configured to output a plurality of second sub fail detection signals by combining the plurality of second test data signals; and
a signal combination section configured to output a second fail detection signal by combining the plurality of second sub fail detection signals.

6. The test circuit according to claim 1, wherein the common fail detection unit comprises:
a plurality of sub common fail detection sections configured to output a plurality of sub common fail detection signals by combining the plurality of first and second test data signals; and
a signal combination section configured to output a common fail detection signal by combining the plurality of sub common fail detection signals.

7. The test circuit according to claim 1, wherein the fail determination unit comprises:
a fail detection combination section configured to output a fail combination signal by combining a first fail detection signal outputted from the first fail detection unit, a second fail detection signal outputted from the second fail detection unit, and a common fail detection signal outputted from the common fail detection unit;
a first signal output section configured to output a first final fail detection signal by combining the fail combination signal and the first fail detection signal; and
a second signal output section configured to output a second final fail detection signal by combining the fail combination signal and the second fail detection signal.

8. A test circuit of a semiconductor memory apparatus, comprising:
a first fail detection unit configured to detect a fail of a memory cell group of a first memory block by combining a plurality of first test data signals outputted from the memory cell group of the first memory block;
a second fail detection unit configured to detect a fail of a memory cell group of a second memory block by combining a plurality of second test data signals outputted from the memory cell group of the second memory block;
a common fail detection unit configured to detect the fail of the memory cell groups of the first and second memory blocks by combining the plurality of first test data signals and the plurality of second test data signals; and
a selection unit configured to output detection results of the first and second fail detection units or a detection result of the common fail detection unit according to a mode selection signal.

9. The test circuit according to claim 8, wherein the common fail detection unit outputs the detection result that the memory cell groups of the first and second memory blocks are failed, when any one of the memory cell groups of the first memory block and the second memory block is failed.

10. The test circuit according to claim 8, wherein the first fail detection unit comprises:
a plurality of first sub fail detection sections configured to output a plurality of first sub fail detection signals by combining the plurality of first test data signals; and
a signal combination section configured to output a first fail detection signal by combining the plurality of first sub fail detection to signals.

11. The test circuit according to claim 8, wherein the second fail detection unit comprises:
a plurality of second sub fail detection sections configured to output a plurality of second sub fail detection signals by combining the plurality of second test data signals; and
a signal combination section configured to output a second fail detection signal by combining the plurality of second sub fail detection signals.

12. The test circuit according to claim 8, wherein the common fail detection unit comprises:
a plurality of sub common fail detection sections configured to output a plurality of sub common fail detection signals by combining the plurality of first and second test data signals; and
a signal combination section configured to output a common fail detection signal by combining the plurality of sub common fail detection signals.

13. The test circuit according to claim 8, wherein the selection unit comprises a plurality of switching sections,
wherein the plurality of switching sections output a common fail detection signal outputted from the common fail detection unit when the mode selection signal is activated, and
wherein the plurality of switching sections output a first fail detection signal and a second fail detection signal outputted from the first fail detection unit and the second fail detection unit when the mode selection signal is deactivated.

14. A semiconductor memory apparatus comprising:
a first fail detection unit configured to detect a fail of a memory cell group of a first memory block by combine a plurality of first test data signals outputted from the memory cell group of the first memory block;
a second fail detection unit configured to detect a fail of a memory cell group of a second memory block by combining a plurality of second test data signals outputted from the memory cell group of the second memory block;
a common fail detection unit configured to detect a fail of the memory cell groups of the first and second memory blocks by combining the plurality of first test data signals and the plurality of second test data signals;
a fail determination unit configured to output detection results of the first and second fail detection units or a detection result of the common fail detection unit;
a redundancy memory block including a plurality of redundancy memory cell groups; and
a repair unit configured to replace the memory cell groups of the first and second memory blocks with the redundancy memory cell groups based on the detection result outputted from the fail determination unit.

15. The semiconductor memory apparatus according to claim 14, wherein the fail determination unit outputs the detection results of the first and second fail detection units or the detection result of the common fail detection unit according to the detection results of the first and second fail detection units.

16. The semiconductor memory apparatus according to claim 15,
wherein, when one of the first fail detection unit and the second fail detection unit detects the fail of the memory cell group of the corresponding memory block, the fail determination unit outputs the detection result of the fail detection unit that detects the fail, and
wherein, when the first fail detection unit and the second fail detection unit detect no fail in the memory cell groups of the corresponding memory blocks, the fail determination unit outputs the detection result of the common fail detection unit.

17. The semiconductor memory apparatus according to claim 14,
wherein, when the fail determination unit outputs the detection result of the first fail detection unit or the second fail detection unit, the repair unit replaces the failed memory cell group of the memory block with the redundancy memory cell group, and
wherein, when the fail determination unit outputs the detection result of the common fail detection unit, the repair unit simultaneously replaces the corresponding memory cell groups of the first and second memory blocks with the redundancy memory cell group.

18. The semiconductor memory apparatus according to claim 14, wherein the fail determination unit outputs the detection results of the first and second fail detection units or the detection result of the common fail detection unit according to a mode selection signal.

19. The semiconductor memory apparatus according to claim 14, wherein the common fail detection unit outputs the detection result that the memory cell groups of the first and second memory blocks are failed when any one of the memory cell groups of the first memory block and the second memory block is failed.

20. The semiconductor memory apparatus according to claim 14, wherein the first fail detection unit comprises:
a plurality of first sub fail detection sections configured to output a plurality of first sub fail detection signals by combining the plurality of first test data signals; and
a signal combination section configured to output a first fail detection signal by combining the plurality of first sub fail detection signals.

21. The semiconductor memory apparatus according to claim 14, wherein the second fail detection unit comprises:
a plurality of second sub fail detection sections configured to output a plurality of second sub fail detection signals by combining the plurality of second test data signals; and
a signal combination section configured to output a second fail detection signal by combining the plurality of second sub fail detection signals.

22. The semiconductor memory apparatus according to claim 14, wherein the common fail detection unit comprises:
a plurality of sub common fail detection sections configured to output a plurality of sub common fail detection signals by combining the plurality of first and second test data signals; and
a signal combination section configured to output a common fail detection signal by combining the plurality of sub common fail detection signals.

23. The semiconductor memory apparatus according to claim 14, wherein the fail determination unit comprises:
a fail detection combination section configured to output a fail combination signal by combining a first fail detection signal outputted from the first fail detection unit, a second fail detection signal outputted from the second fail detection unit, and a common fail detection signal outputted from the common fail detection unit;
a first signal output section configured to output a first final fail detection signal by combining the fail combination signal and the first fail detection signal; and
is a second signal output section configured to output a second final fail detection signal by combining the fail combination signal and the second fail detection signal.
